(19) United States
(12) Patent Application Publication
(10) Pub. No.: US 2020/0105789 A1
(43) Pub. Date: Apr. 2, 2020

(54) ARRAY SUBSTRATE, METHOD OF MANUFACTURING THE SAME, AND DISPLAY PANEL

(71) Applicant: BOE Technology Group Co., Ltd., Beijing (CN)

(72) Inventors: Jingang Fang, Beijing (CN); Luke Ding, Beijing (CN); Jun Liu, Beijing (CN); Leilei Cheng, Beijing (CN)

(21) Appl. No.: 16/394,381

(22) Filed: Apr. 25, 2019

(30) Foreign Application Priority Data
Sep. 30, 2018 (CN) 201811163079.4

(51) Int. Cl. H01L 27/12; H01L 29/786; G03F 7/16; G03F 7/20; G03F 7/26

(52) U.S. Cl. CPC H01L 27/124; H01L 27/1225; H01L 27/1255; H01L 27/127; H01L 27/1288; H01L 27/3262; H01L 29/7869; G03F 7/16; G03F 7/20; G03F 7/26; G03F 7/2024; H01L 29/78633

(57) ABSTRACT

Embodiments of the present disclosure provide an array substrate and a method of manufacturing the same and a display pane. The array substrate includes: a substrate, and a light shielding metal layer, a buffer layer, a thin film transistor disposed on the substrate in order. The thin film transistor includes a gate electrode, an active layer, and a source electrode and a drain electrode. The buffer layer includes a first via hole that exposes the light shielding metal layer. The source electrode is electrically connected to the light shielding metal layer through the conductive structure in the first via hole.

### CROSS-REFERENCE TO RELATED APPLICATION

This application claims the benefit of Chinese Patent Application No. 201811163079.4, filed on Sep. 30, 2018, entitled “ARRAY SUBSTRATE, METHOD OF MANUFACTURING THE SAME, AND DISPLAY PANEL”, filed with the State Intellectual Property Office of China on Sep. 30, 2018, the whole disclosure of which is incorporated herein by reference.

### TECHNICAL FIELD

Embodiments of the present disclosure relate to display technology field, and particularly to an array substrate, a method of manufacturing the same, and a display panel.

### DESCRIPTION OF RELATED ART

The array substrate, as a main component in a liquid crystal display, includes a large number of components, and involves arrangement of a plurality of layers and etching of a via hole in the manufacturing process. It is necessary to further improve the layout of the array substrate.

### SUMMARY

Embodiments of the present disclosure provide an array substrate and a method of manufacturing the same and a display panel, which may improve contact between a source electrode and a light shielding metal layer.

As an aspect, there is provided an array substrate including:

a substrate;

a light shielding metal layer on the substrate;

a buffer layer on a side, on which the light shielding metal layer is, of the substrate including the light shielding metal layer; and

a thin film transistor on a side of the buffer layer away from the substrate, the thin film transistor including a gate electrode, an active layer, and a source electrode and a drain electrode;

the array substrate further includes:

a first via hole in the buffer layer, the first via hole exposing the light shielding metal layer; and

a conductive structure in the first via hole, the source electrode being electrically connected to the light shielding metal layer through the conductive structure.

In an embodiment, the thin film transistor is a top gate type thin film transistor;

the active layer includes a channel region, a source electrode region and a drain electrode region on either side of the channel region, an orthographic projection of the channel region on the substrate overlapping an orthographic projection of the gate electrode on the substrate; the source electrode is electrically connected to the conductive structure through a second via hole in the interlayer insulating layer and is further electrically connected to the source electrode region through a third via hole in the interlayer insulating layer, and the drain electrode is electrically connected to the drain electrode region through a fourth via hole in the interlayer insulating layer; the source electrode region, the drain electrode region, and the conductive structure are obtained by converting a corresponding portion of a same semiconductor film into a conductor, and a first pattern of the conductor converted from the semiconductor film includes the source electrode region and the drain electrode region, and a second pattern of the conductor converted from the semiconductor film includes the conductive structure.

In an embodiment,

the thin film transistor is a top gate electrode thin film transistor; the active layer includes a channel region, a source electrode region and a drain electrode region on either side of the channel region, an orthographic projection of the channel region on the substrate overlapping an orthographic projection of the gate electrode on the substrate; the source electrode is electrically connected to the conductive structure through a second via hole in the interlayer insulating layer and is further electrically connected to the source electrode region through a third via hole in the interlayer insulating layer; and the drain electrode is electrically connected to the drain electrode region through a fourth via hole in the interlayer insulating layer;

the gate electrode and the conductive structure are formed by the same conductive film, a first pattern of the conductive film includes the gate electrode, and a second pattern of the conductive film includes the conductive structure.

In an embodiment, the thin film transistor further includes a gate insulating layer disposed between the active layer and the gate electrode; and

an orthographic projection of the gate insulating layer on the substrate completely overlaps an orthographic projection of the channel region on the substrate.

In an embodiment, the thin film transistor further includes a gate insulating layer disposed between the active layer and the gate electrode; and

an orthographic projection of the gate insulating layer on the substrate completely overlaps an orthographic projection of the channel region on the substrate.

In an embodiment, the thin film transistor is a bottom gate type thin film transistor; and

the conductive structure and the gate electrode are obtained by the same conductive film, wherein a first pattern of the conductive film includes the gate electrode, and a second pattern of the conductive film includes the conductive structure, the bottom gate type thin film transistor includes a gate insulating layer and the source electrode is electrically connected to the conductive structure through a fifth via hole in the gate insulating layer.

In an embodiment, the array substrate further includes a storage capacitor;

the storage capacitor includes a first electrode, a second electrode, and a third electrode that are stacked, and the first electrode, the second electrode, and the third electrode are insulated from one another.

In an embodiment, the array substrate further includes a pixel electrode, the pixel electrode being electrically connected to the source electrode of the thin film transistor; and

the first electrode is disposed in the same layer as the pixel electrode, the second electrode is disposed in the same layer as the source electrode and the drain electrode, and the third electrode is disposed in the same layer as the conductive structure.

In an embodiment, the array substrate is an organic light-emitting diode array substrate, the organic light-emitting diode array substrate further includes an organic light-emitting diode type light-emitting device, and the organic light-emitting diode type light-emitting device includes an anode, a functional layer of an organic material, and a cathode, which are sequentially stacked; and

in a case where the array substrate includes a pixel electrode, the pixel electrode functions as the anode.

In an embodiment, the thin film transistor is a double-gate type thin film transistor, and the gate electrode is electrically connected to the light shielding metal layer via a conductive block and the conductive structure.

As an aspect, there is provided a display panel including the above mentioned array substrate.

As an aspect, there is provided a method of manufacturing an array substrate, the method including:

forming a light shielding metal layer and a buffer layer on the substrate in order, wherein the buffer layer includes a first via hole, the first via hole exposing the light shielding metal layer; and

forming a thin film transistor and a conductive structure on a side of the buffer layer away from the substrate, wherein a source electrode of the thin film transistor is electrically connected to the light shielding metal layer through the conductive structure located in the first via hole.

In an embodiment, the thin film transistor is a top gate type thin film transistor;

the forming the thin film transistor and the conductive structure, including:

forming a semiconductor film on the side of the buffer layer away from the substrate, and forming a photoresist over the semiconductor film;

exposing and developing the photoresist to form a first photoresist pattern;

etching the semiconductor film to form a first pattern of the semiconductor film and a second pattern of the semiconductor film; and

conducting a conductor transformation treatment on the first pattern of the semiconductor film and the second pattern of the semiconductor film, the first pattern of the semiconductor film being subjected to the conductor transformation treatment to form the active layer, and the second pattern of the semiconductor film being subjected to the conductor transformation treatment to form the conductive structure;

wherein the active layer includes a channel region, a source electrode region and a drain electrode region on either side of the channel region, an orthographic projection of the channel region on the substrate overlapping an orthographic projection of the gate electrode on the substrate; the source electrode being electrically connected to the conductive structure through a second via hole in the interlayer insulating layer and being further electrically connected to the source electrode region through a third via hole in the interlayer insulating layer; and the drain electrode is electrically connected to the drain electrode region through a fourth via hole in the interlayer insulating layer.

In an embodiment, a material of the semiconductor film is a metal oxide;

the conducting a conductor transformation treatment on the first pattern of the semiconductor film and the second pattern of the semiconductor film, including:

conducting a conductor transformation treatment on the first pattern of the semiconductor film and the second pattern of the semiconductor film by a chemical vapor deposition method using a gas containing hydrogen atoms; or

conducting a conductor transformation treatment on the first pattern and the second pattern by dry etching.

In an embodiment, after forming the first pattern of the semiconductor film and the second pattern of the semiconductor film, and before conducting the conductor transformation treatment on the first pattern of the semiconductor film and the second pattern of the semiconductor film, the forming the thin film transistor further includes:

forming an insulating film and a conductive film sequentially on a side of the first pattern of the semiconductor film and the second pattern of the semiconductor film away from the substrate, and forming a photoresist over the conductive film;

exposing and developing the photoresist to form a second photoresist pattern;

wet-etching the conductive film to form the gate electrode;

dry-etching the insulating film to form a gate insulating layer of the thin film transistor;

the conducting a conductor transformation treatment on the first pattern of the semiconductor film and the second pattern of the semiconductor film including:

covering the first pattern of the semiconductor film with the second photoresist pattern, and conducting a conductor transformation treatment on the first pattern of the semiconductor film to obtain the source electrode region and the drain electrode region including a conductor converted; and conducting a conductor transformation treatment on the second pattern of the semiconductor film to obtain the conductive structure.

In an embodiment, the thin film transistor is a bottom gate type thin film transistor;

the forming the thin film transistor and the conductive structure including:

forming a conductive film on the side of the buffer layer away from the substrate, and forming a photoresist over the conductive film;

exposing and developing the photoresist to form a third photoresist pattern; and

etching the conductive film to form a gate electrode metal layer, the gate electrode metal layer including the gate electrode and the conductive structure.

In an embodiment, the method further includes:

forming a first electrode, a second electrode, and a third electrode sequentially on the substrate, the first electrode, the second electrode, and the third electrode being insulated from one another and constituting a storage capacitor.

In an embodiment, the array substrate further includes a pixel electrode;

the first electrode and the pixel electrode are obtained by a single patterning process, the second electrode and the source electrode and the drain electrode are obtained by a single patterning process, and the third electrode and the conductive structure are obtained by a single patterning process.

### BRIEF DESCRIPTION OF THE DRAWINGS

The drawings illustrated herein are provided to further understand the present disclosure and constitute a portion of the present disclosure. The exemplary embodiments in the present disclosure and their description are used for interpret the present disclosure, but do not limit the present disclosure. In the drawings:

FIG. 1 is a schematic view of an array substrate in related art;

FIG. 2 is a schematic view of an array substrate provided by embodiments of the present disclosure;

FIG. 3 is a schematic view of an array substrate provided by embodiments of the present disclosure;

FIG. 4 is a schematic view of an array substrate provided by embodiments of the present disclosure;

FIG. 5 is a schematic view of an array substrate provided by embodiments of the present disclosure;

FIG. 6 is a schematic flow chart of manufacturing an array substrate provided by embodiments of the present disclosure;

FIG. 7 is a schematic view of an array substrate provided by embodiments of the present disclosure;

FIG. 8 is a schematic view of process of manufacturing an array substrate provided by embodiments of the present disclosure;

FIG. 9 is a schematic flow chart of manufacturing an array substrate provided by embodiments of the present disclosure;

FIG. 10 is a schematic view of process of manufacturing an array substrate provided by embodiments of the present disclosure;

FIG. 11 is a schematic view of process of manufacturing an array substrate provided by embodiments of the present disclosure;

FIG. 12 is a schematic view of process of manufacturing an array substrate provided by embodiments of the present disclosure;

FIG. 13 is a schematic flow chart of manufacturing an array substrate provided by embodiments of the present disclosure;

FIG. 14 is a schematic view of process of manufacturing an array substrate provided by embodiments of the present disclosure;

FIG. 15 is a schematic view of process of manufacturing an array substrate provided by embodiments of the present disclosure;

FIG. 16 is a schematic view of process of manufacturing an array substrate provided by embodiments of the present disclosure;

FIG. 17 is a schematic view of process of manufacturing an array substrate provided by embodiments of the present disclosure;

FIG. 18 is a schematic flow chart of manufacturing an array substrate provided by embodiments of the present disclosure;

FIG. 19 is a schematic view of process of manufacturing an array substrate provided by embodiments of the present disclosure; and

FIG. 20 is a schematic view of process of manufacturing an array substrate provided by embodiments of the present disclosure.

### DETAILED DESCRIPTION

The technical solutions in the embodiments of the present disclosure are clearly and completely described in the following with reference to the accompanying drawings in the embodiments of the present disclosure. It is obvious that the described embodiments are only a part of embodiments of the present disclosure, and not all of the embodiments. All other embodiments obtained by those of ordinary skill in the art based on the embodiments of the present disclosure without creative efforts are within the scope of the present disclosure.

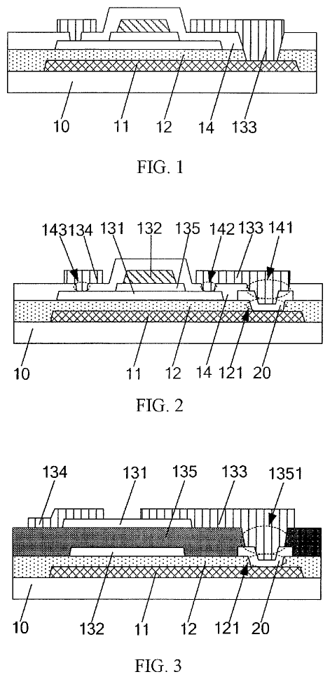

In the related art relating to an array substrate, for example, as shown in FIG. 1, an array substrate includes a light shielding metal layer 11 and a buffer layer 12 which are disposed between a substrate 10 and a thin film transistor and sequentially disposed on the substrate 10. In order to achieve better stability of the oxide characteristics, the buffer layer 12 is made of a pure silicon oxide, and the thickness of the buffer layer 12 is relatively large. When patterns of the buffer layer 12 and an interlayer insulating layer 14 are formed by dry etching, in order to ensure complete etching, a large amount of over-etching is required, that is, a light shielding metal layer 11 located on the side of the buffer layer 12 close to the substrate 10 is also etched, wherein the greater the sum of the thicknesses of the buffer layer 12 and the interlayer insulating layer 14 is, the greater the required amount of over-etch is, which thereby may cause a source electrode 133 of the thin film transistor to be in poor contact with the light-shielding metal layer 11.

Embodiments of the present disclosure provide an array substrate, as shown in FIGS. 2 and 3, including a substrate 10, and a light shielding metal layer 11, a buffer layer 12, and a thin film transistor which are sequentially disposed on the substrate 10. In other words, the light shielding metal layer 11 is on the substrate 10, the buffer layer 12 is located on a side, on which the light shielding metal layer is, of the substrate including the light shielding metal layer, and the thin film transistor is located on a side of the buffer layer away from the substrate.

The thin film transistor includes a gate electrode 132, an active layer 131, and a source electrode 133 and a drain electrode 134, the buffer layer 12 includes a first via hole 121, which is configured to expose the light shielding metal layer 11 and the source electrode 133 is electrically connected to the light shielding metal layer 11 via a conductive structure 20 disposed in the first via hole 121.

Here, as the source electrode 133 is electrically connected to the light shielding metal layer 11 via the conductive structure 20, a parasitic capacitance between the light shielding metal layer 11 and the gate electrode 132 can be avoided, which improves the working efficiency of the array substrate.

According to embodiments of the present disclosure, the light shielding metal layer 11 is made of a metal and has functions of conduction and shielding light. In the embodiment, a thickness of the light shielding metal layer 11 should be sufficient to block light.

For example, the light shielding metal layer 11 may be made of a high temperature and oxidation resistant metal material such as molybdenum, molybdenum-niobium alloy or molybdenum-titanium alloy.

According to embodiments of the present disclosure, the array substrate is an array substrate for display, and the array substrate can be used for an organic light emitting diode (referred to as OLED) display panel, and can also be used for a liquid crystal display (referred to as LCD) panel.

In an embodiment where the array substrate is used for an OLED display panel, the OLED display panel further includes an OLED light emitting device, the OLED light emitting device including an anode, an organic material functional layer and a cathode which are sequentially stacked; wherein the OLED light emitting device may be a top-emitting structure, or may also be a bottom-emitting structure, or may be a double-sided emitting structure in which both the anode and the cathode are transparent.

In the embodiment of the present disclosure where the OLED light-emitting device is a bottom-emitting structure, or the OLED light-emitting device is a double-sided emitting structure in which both the anode and the cathode are transparent, the light-shielding metal layer 11 can further be used as a black matrix defining a sub-pixel region of the array substrate.

In the above embodiment, since the light shielding metal layer 11 is electrically connected to the source electrode 133 of the thin film transistor through the conductive structure 20, it is only necessary to dispose the light shielding metal layer 11 in a region where an orthographic projection of the thin film transistor on the substrate 10 is located. Those skilled in the art should know that the area where the thin film transistor is located cannot transmit light, and therefore, the light shielding metal layer 11 does not affect light transmission through the array substrate.

Of course, the light shielding metal layer 11 may also be disposed in other areas according to actual needs.

According to embodiments of the present disclosure, the conductive structure 20 may all be disposed in the first via hole 121; alternatively, as shown in FIGS. 2 and 3, a portion of the conductive structure 20 is disposed in the first via hole 121, and another portion thereof is disposed on a surface of the buffer layer 12 away from the substrate 10. In the embodiment where the conductive structure 20 is all disposed in the first via hole 121, the conductive structure 20 may completely fill the first via hole 121 or partially fill the first via hole 121.

Of course, a size of the conductive structure 20 at least satisfies that the source electrode 133 can be electrically connected to the light shielding metal layer 11 through the conductive structure 20, and the conductive structure 20 is not electrically connected to other structures in the thin film transistor (for example, the conductive structure is not electrically connected to the gate electrode).

According to embodiments of the present disclosure, the conductive structure 20 may be manufactured in various ways. The conductive structure 20 may be separately formed of a single film; and the conductive structure 20 may also be formed by the same film as other structures on the array substrate.

In an embodiment where the conductive structure 20 and the other structures on the array substrate are formed from the same film, the conductive structure 20 can be obtained by the same manufacturing process as the other structures on the array substrate, or can be obtained by a different manufacturing process from the other structures on the array substrate.

According to embodiments of the present disclosure, as shown in FIG. 2, the thin film transistor may be of a top gate type thin film transistor; as shown in FIG. 3, the thin film transistor may also be of a bottom gate type thin film transistor. A top-gate thin film transistor has a higher on-state current (Ion), higher aperture ratio, and better stability than a bottom-gate thin film transistors.

As shown in FIG. 2, the top gate type thin film transistor includes an active layer 131, a gate insulating layer 135, a gate electrode 132, and a source electrode 133 and a drain electrode 134 in contact with the active layer 131, which are sequentially disposed on the substrate 10. The gate electrode 132 is isolated from the source electrode 133 and the drain electrode 134 by an interlayer insulating layer 14.

As shown in FIG. 3, the bottom gate type thin film transistor includes a gate electrode 132, a gate insulating layer 135, an active layer 131, and a source electrode 133 and a drain electrode 134 in contact with the active layer 131 sequentially disposed on a substrate 10.

As for the top gate type thin film transistor shown in FIG. 2, the source electrode 133 is electrically connected to the conductive structure 20, located in the first via hole 121, through a second via hole 141 in the interlayer insulating layer 14.

As for the bottom gate type thin film transistor shown in FIG. 3, the source electrode 133 is electrically connected to the conductive structure 20, located in the first via hole 121, through a via hole in the gate insulating layer 135.

In embodiments of the present disclosure provide an array substrate, the conductive structure 20 is provided in the first via hole 121, the conductive structure 20 may be formed after formation of the buffer layer 12 including the first via hole 121 and before formation of the interlayer insulating layer 14 or the gate insulating layer 135, compared to the related art. On the one hand, since only the buffer layer 12 is needed to be etched to form the first via hole 121 before formation of the conductive structure 20, and the thickness of the buffer layer 12 (the thickness of the buffer layer is usually 4000˜5000 Å) is less than the sum of the thicknesses of the buffer layer 12 and the interlayer insulating layer 14 (a thickness of the interlayer insulating layer is usually 5000 to 6000 Å), or the thickness of the buffer layer 12 is less than the sum of the thicknesses of the buffer layer 12 and the gate insulating layer 135, when the buffer layer 12 is over-etched, the etching amount of the light shielding metal layer 11 is less than that of the related art, and a thickness of a portion of the light shielding metal layer 11 whose orthographic projection on the substrate 10 overlaps an orthographic projection of the first via hole 121 on the substrate 10 is greater. On the other hand, the source electrode 133 is required to be electrically connected to the conductive structure 20 through the second via hole 141 in the interlayer insulating layer 14 or the via hole in the gate insulating layer 135 and the conductive structure 20 can protect the light shielding metal layer 11 and avoid the light shielding metal layer 11 from being etched during formation of the interlayer insulating layer 14 or the gate insulating layer 135. In summary, compared with the related art, in the embodiment, the thickness of the portion of the light shielding metal layer 11 whose orthographic projection on the substrate 10 overlaps the orthographic projection of the first via hole 121 on the substrate 10 is greater and thereby problem of poor contact between the source electrode 133 and the light shielding metal layer 11 is alleviated.

In an embodiment, as shown in FIG. 2, the thin film transistor is a top gate type thin film transistor; the active layer 131 includes a channel region, a source electrode region and a drain electrode region on either side of the channel region respectively, an orthographic projection of the channel region on the substrate 10 overlaps an orthographic projection of the gate electrode 132 on the substrate 10; the source electrode 133 is electrically coupled to the conductive structure 20 through the second via hole 141 in the interlayer insulating layer 14, and is also electrically connected to the source electrode region through the third via hole 142 in the interlayer insulating layer 14; the drain electrode 134 is electrically connected to the drain electrode region through the fourth via hole 143 in the interlayer insulating layer 14; the active layer 131 and the conductive structure 20 are obtained by the same semiconductor film, and the source electrode region, the drain electrode region, and the conductive structure 20 are obtained by a conductor transformation treatment on the semiconductor film.

Here, in order to improve the ohmic contact between the source electrode 133 and the drain electrode 134 and the active layer 131 such that the top gate type thin film transistor has better switching characteristics, the source electrode region and the drain electrode region in the active layer 131 are both obtained by a conductor transformation treatment.

According to embodiments of the present disclosure, the orthographic projection of the channel region on the substrate 10 may exactly completely overlap the orthographic projection of the gate electrode 132 on the substrate 10. According to embodiments of the present disclosure, the orthographic projection of the channel region on the substrate 10 may also exceed the area where the orthographic projection of the gate electrode 132 on the substrate 10 is located. Herein, the orthographic projection of the channel region on the substrate 10 does not exactly coincide with the orthographic projection of the source electrode 133 and drain electrode 134 on the substrate 10.

According to embodiments of the present disclosure, the semiconductor thin film may be made of a plurality of materials as long as the material is selected such that the source electrode region, the drain electrode region, and the conductive structure 20 having conductivity may be obtained upon a conductor transformation treatment on portions of the semiconductor thin film.

For example, the material for forming the semiconductor thin film may include a metal oxide, such as at least one of indium gallium zinc oxide (IGZO) or indium tin zinc oxide (ITZO).

The material for forming the semiconductor film may also include polysilicon.

According to embodiments of the present disclosure, the active layer 131 and the conductive structure 20 may be formed by using a semiconductor thin film through various processes. For example, patterns of the active layer 131 and the conductive structure 20 may be formed by a patterning process, wherein the patterns of the active layer 131 and the conductive structure 20 may be formed by a single patterning process, or of course, the patterns of the active layer 131 and the conductive structure 20 may also be formed by different patterning processes. In an embodiment, the patterns of the active layer 131 and the conductive structure 20 is formed by the semiconductor film by a single patterning process simplifying the fabrication process of the array substrate and reducing the number of masks.

According to embodiments of the present disclosure, a particular portion of the material of the semiconductor thin film may be converted into a conductor in various ways.

In an embodiment, the material of the semiconductor thin film is a metal oxide, and the semiconductor thin film may be subjected to a conductor transformation treatment using a gas containing hydrogen atom by a chemical vapor deposition (CVD) method The gas containing hydrogen atom may be hydrogen (H₂) or ammonia (NH₃), and the hydrogen atom (or ion) may be used to perform an ionic bombardment on the metal oxide to remove the oxygen ions in the metal oxide. In an embodiment, the semiconductor film may be subjected to a conductor transformation treatment by dry etching. Since the dry etching has no etching effect on the metal oxide, atom contained in the gas used during the dry etching may be utilized to perform a bombardment on the metal oxide, breaking the chemical bond between the metal and the oxygen in the metal oxide and thereby removing the oxygen of the metal oxide. The gas used for the dry etching may be helium, the atom for performing a bombardment on the metal oxide may be helium atom.

According to embodiments of the present disclosure, referring to FIGS. 2, 4, 5, and 6, the semiconductor film is subjected to a conductor transformation treatment. Herein, it is assumed that the pattern of the active layer 131 to be formed corresponds to a first pattern and the pattern of the conductive structure 20 to be formed corresponds to the second pattern. After the first pattern and the second pattern are formed, the first pattern is subjected to a conductor transformation treatment to obtain a source electrode region and a drain electrode region having conductivity; and the second pattern is subjected to a conductor transformation treatment to obtain the conductive structure 20.

In the embodiment, the first pattern and the second pattern may be simultaneously subjected to a conductor transformation treatment, or the first pattern and the second pattern may be separately subjected to a conductor transformation treatment. In an embodiment, simultaneously performing the conductor transformation treatment on the first pattern and the second pattern can simplify the fabrication process of the array substrate and reduce the number of masks. Since the active layer and the conductive structure are formed from the same semiconductor film, after the conductor transformation treatment, the portion of the semiconductor film corresponding to the source electrode region and the drain electrode region are converted into the first pattern of a conductor, and the portion of the semiconductor film corresponding to the conductive structure 20 is converted into the second pattern of the conductor, or in other words, the first pattern of the conductor converted from the semiconductor film includes the source electrode region and the drain electrode region, and the second pattern of the conductor converted from the semiconductor film includes the conductive structure.

In the embodiment of the present disclosure, since the patterns of the active layer 131 and the conductive structure 20 are formed by the same semiconductor film, the fabrication process can be simplified and the number of masks can be reduced.

Further, in an embodiment, as shown in FIG. 2, the thin film transistor further includes a gate insulating layer 135 between the active layer 131 and the gate electrode 132; an orthographic projection of the gate insulating layer 135 on the substrate 10 completely overlaps or coincide with the orthographic projections of the channel region on the substrate 10.

Herein, the gate insulating layer 135 may be formed by dry etching, such that the orthographic projection of the gate insulating layer 135 on the substrate 10 completely overlaps or coincides with an orthographic projection of a photoresist pattern for forming the gate insulating layer 135 on the substrate 10. On the basis of this, the photoresist pattern for forming the gate insulating layer 135 may be also used to cover the first pattern of the active layer 131 to be formed so as to conduct a conductor transformation treatment on the uncovered portions of the first pattern. Herein, the portion covered by the photoresist pattern is the channel region of the active layer 131, and the orthographic projection of the gate insulating layer 135 on the substrate 10 completely overlaps or coincides with the orthographic projection of the channel region on the substrate 10.

In the embodiment of the present disclosure, the orthographic projection of the gate insulating layer 135 on the substrate 10 completely overlaps the orthographic projection of the channel region on the substrate 10, that is, the photoresist pattern for forming the gate insulating layer 135 may be also used for conducting the conductor transformation treatment on the semiconductor film, thereby simplifying the fabrication process of the array substrate and reducing the number of masks.

According to embodiments of the present disclosure, as for the top gate type thin film transistor, referring to FIG. 2, the conductive structure 20 and the gate electrode may be obtained by the same conductive film.

According to embodiments of the present disclosure, referring to FIGS. 2, 4, 5, 6, 16, 17, patterns of the conductive structure 20 and the gate electrode 132 may be formed using a patterning process, wherein the patterns of the conductive structure 20 and the gate electrode 132 may be formed by a single patterning process, of course, the patterns of the conductive structure 20 and the gate electrode 132 may be formed by different patterning processes. In an embodiment, the patterns of the conductive structure 20 and the gate electrode 132 is formed by a single patterning process to simplify the fabrication process of the array substrate and reduce the number of masks. In the embodiment, the first pattern of the conductive film includes the gate electrode 132, and the second pattern of the conductive film includes the conductive structure 20.

According to the embodiment of the present disclosure, since the gate electrode 132 and the conductive structure 20 are formed before the interlayer insulating layer 14 is formed, the light shielding metal layer 11 is over-etched only during formation of the first via hole 121, before forming the conductive structure 20, and the over-etching amount of the light shielding metal layer 11 is less than that of the related art. Thus, a thickness of a portion of the light shielding metal layer 11 whose orthographic projection on the substrate 10 overlaps the orthographic projection of the first via hole 121 on the substrate 10 is greater, and the problem of poor contact between the source electrode 133 and the light shielding metal layer 11 may be alleviated.

In an embodiment, for example, as shown in FIG. 3, the thin film transistor is a bottom gate type thin film transistor; the conductive structure 20 and the gate electrode 132 are obtained by the same conductive film, and the bottom gate type thin film transistor includes a gate insulating layer 135, and the source electrode 133 is electrically connected to the conductive structure 20 through the fifth via hole 1351 in the gate insulating layer 135.

According to embodiments of the present disclosure, the conductive structure 20 and the gate electrode 132 may be formed by a conductive film by various processes. For example, in an embodiment, the patterns of the conductive structure 20 and the gate electrode 132 may be formed by a patterning process, wherein the patterns of the conductive structure 20 and the gate electrode 132 may be formed by a single patterning process, or of course, by different patterning processes. In an embodiment, the patterns of the conductive structure 20 and the gate electrode 132 is formed by a single patterning process to simplify the fabrication process of the array substrate and reduce the number of masks. In the embodiment, the first pattern of the conductive film includes the gate electrode 132, and the second pattern of the conductive film includes the conductive structure 20.

In the embodiment of the present disclosure, since the patterns of the conductive structure 20 and the gate electrode 132 are formed by the same conductive film, the fabrication processes can be simplified and the number of masks can be reduced. Further, compared to the case where the conductive structure 20 and the active layer 131 are formed by the same semiconductor film, the embodiment of the present disclosure may omit the step of conducting the conductor transformation treatment on the portion of the semiconductor film corresponding to the conductive structure 20.

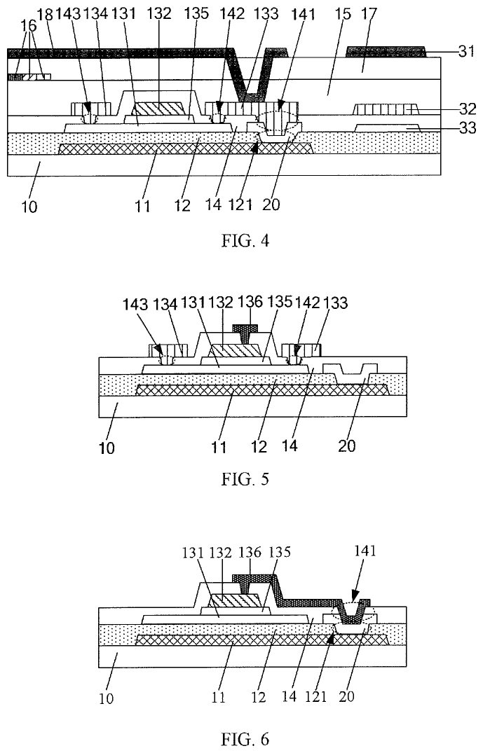

In an embodiment, as shown in FIG. 4, the array substrate may further include a storage capacitor; the storage capacitor includes a first electrode 31, a second electrode 32, and a third electrode 33, which are stacked, and are insulated from one another. FIG. 4 only shows the storage capacitor in the embodiment including the top gate type thin film transistor. In the embodiment including a bottom gate type thin film transistor, the storage capacitor may be included.

It should be noted that “the first electrode 31, the second electrode 32, and the third electrode 33 are insulated from one another” means that every two of the first electrode 31, the second electrode 32, and the third electrode 33 are insulated from each other. That is, the first electrode 31 and the second electrode 32 are insulated from each other, the first electrode 31 and the third electrode 33 are insulated from each other, and the second electrode 32 and the third electrode 33 are insulated from each other.

According to embodiments of the present disclosure, the first electrode 31, the second electrode 32, and the third electrode 33 may constitute a capacitance of a sandwiched structure.

In the embodiment of the present disclosure, the storage capacitance of the sandwich structure can reduce an area of the orthographic projection of the storage capacitor on the substrate 10 and in turn increase aperture ratio of the array substrate while obtaining the same capacitance value of the storage capacitor as the storage capacitor having two electrodes.

Further, in an embodiment, as shown in FIG. 4, the array substrate further includes a pixel electrode 18, and the pixel electrode 18 is electrically connected to the source electrode 133 of the thin film transistor; the first electrode 31 is disposed in the same layer as the pixel electrode 18, and the second electrode 32 is provided in the same layer as the source electrode 133 and the drain electrode 134, and the third electrode 33 is disposed in the same layer as the conductive structure 20. FIG. 4 only shows the storage capacitor in the embodiment including the top gate type thin film transistor. In the embodiments including a bottom gate type thin film transistor, the storage capacitor may also be included.

According to embodiments of the present disclosure, when the array substrate is used for an LCD display panel, the pixel electrode 18 cooperates with the common electrode to drive the liquid crystal to deflect; when the array substrate is used for an OLED display panel, the pixel electrode may serve as an anode in an OLED light-emitting device.

According to embodiments of the present disclosure, the first electrode 31, the pixel electrode 18, the second electrode 32, the source electrode 133 and the drain electrode 134, the third electrode 33, and the light shielding metal layer 11 are all constituted by conductive materials. In an embodiment, the first electrode 31 and the pixel electrode 18 may be formed from different films. In another embodiment, the first electrode 31 and the pixel electrode 18 may also be formed from the same film. In an embodiment, the second electrode 32 and the source electrode 133 and the drain electrode 134 may be formed from different films. In another embodiment, the second electrode 32 and the source electrode 133 and the drain electrode 134 may also be fabricated from the same film. In an embodiment, the third electrode 33 and the conductive structure 20 may be formed from different films. In another embodiment, the third electrode 33 and the conductive structure 20 may also be formed from the same film.

In an embodiment, the first electrode 31 and the pixel electrode 18 are formed from the same film, the second electrode 32 and the source electrode 133 and the drain electrode 134 are formed from the same film, and the third electrode 33 and the conductive structure 20 are formed from the same film. In this way, the manufacturing process of the array substrate may be simplified, and the number of masks may be reduced.

On the basis of the above, the first electrode 31, the second electrode 32, and the third electrode 33 of the storage capacitor may also be disposed in the same layers as other conductive structures on the array substrate, respectively, for example, any one of the first electrode 31, the second electrode 32 and the third electrode 33 may be disposed in the same layer as the gate electrode 132 or the light shielding metal layer 11.

According to embodiments of the present disclosure, as for the top gate type thin film transistor, the gate insulating layer 135 having a pattern is formed on the buffer layer 12, and in the process of forming the gate insulating layer 135, there exists a certain over-etching of the buffer layer 12. This results in poor uniformity of the thickness of the over-etched buffer layer 12, and the material of the buffer layer 12, such as silicon dioxide, is damaged to some extent, and the dielectric constant thereof is changed at the location where over-etching occurs. Therefore, provision of the buffer layer 12 may affect formation of the storage capacitors between the light shielding metal layer 11 under the buffer layer 12 and other electrodes.

Based on this, the first electrode 31 is arranged in the same layer as the pixel electrode 18, the second electrode 32 is arranged in the same layer as the source electrode 133 and the drain electrode 134, and the third electrode 33 is arranged in the same layer as the conductive structure 20; and a planarization layer 17 and a passivation layer 15 are provided as an insulating layer between the first electrode 31 and the second electrode 32, and the interlayer insulating layer 14 is used as an insulating layer between the second electrode 32 and the third electrode 33. On the one hand, there is no need to provide an insulating layer between the first electrode 31 and the second electrode 32, and an insulating layer between the second electrode 32 and the third electrode 33, which simplifies the manufacturing process; on the one hand, the less the spacing between the first electrode 31 and the second electrode 32, and the spacing between the second electrode 32 and the third electrode 33 are, the greater the capacitance of the storage capacitor is. In an embodiment, if the first electrode 31 and the pixel electrode 18 are obtained through the same film, the second electrode 32 and the source electrode 133 and the drain electrode 134 are obtained through the same film, and the third electrode 33 and the conductive structure 20 are obtained through the same film, the first electrode 31, the second electrode 32 and the third electrode 33 may be formed by transparent conductive material as the pixel electrode 18, the source electrode 133 and the drain electrode 134, and the conductive structure 20 are formed by transparent conductive material. With this configuration, the storage capacitor does not affect the aperture ratio of the array substrate.

In an embodiment, the thin film transistor is a top gate type thin film transistor and the conductive structure 20 is not obtained by the same conductive film as the gate electrode 132, and the conductive structure 20 is disposed in the same layer as the gate electrode 132.

The storage capacitor may also include only two electrodes, and the two electrodes of the storage capacitor are disposed respectively in the same layers as any two of the light shielding metal layer 11, the source electrode 133, the gate electrode 132, the conductive structure 20, and the pixel electrode 18, respectively.

In the above embodiment wherein the second electrode 32 and the third electrode 33 are respectively disposed in the same layers as the gate electrode 132 and the conductive structure 20, an insulating layer is needed to be formed between the gate electrode 132 and the conductive structure 20.

Further, in an embodiment, the array substrate is an OLED array substrate, wherein the OLED array substrate further includes an OLED light emitting device, the OLED light emitting device includes an anode, an organic material functional layer and a cathode which are sequentially stacked. In an embodiment where the array substrate includes the pixel electrode 18, the pixel electrode 18 may serve as an anode.

In embodiments of the present disclosure, on the one hand, when the array substrate is an OLED array substrate, and the OLED light emitting device is a bottom emitting structure, or a double-sided emitting structure in which both the anode and the cathode are transparent, the light shielding metal layer 11 may also be used as a black matrix that defines a sub-pixel region of the array substrate; on the other hand, the pixel electrode 18 serves as the anode, which simplifies the fabrication process of the array substrate.

Embodiments of the present disclosure further provide an array substrate, as shown in FIG. 5 and FIG. 6, including a substrate 10, and a light shielding metal layer 11, a buffer layer 12, and a thin film transistor sequentially disposed on the substrate 10, the thin film transistor includes a gate electrode 132 and a gate insulating layer 135; the buffer layer 12 includes a first via hole 121 and the first via hole 121 exposes the light shielding metal layer 11; the gate electrode 132 is electrically connected to the light shielding metal layer 11 through a conductive structure 20 in the first via hole 121.

The thin film transistor can be regarded as a double-gate type thin film transistor, in which the gate electrode 132 is a top gate electrode of the double-gate type thin film transistor, and the light shielding metal layer 11 is a bottom gate electrode of the double-gate type thin film transistor, and the top gate electrode is electrically connected to a conductive block 136 through the via hole in the interlayer insulating layer 14, and the conductive structure 20 is electrically connected to the conductive block 136 through the first via hole 121 and the second via hole 141, so that the top gate electrode (i.e., the gate electrode 132) is electrically connected to the conductive structure 20. Since the gate electrode 132 is electrically connected to the light shielding metal layer 11, no parasitic capacitance is generated between them. It should be understood that, in the embodiment shown in FIG. 6, only a part of the structure of the embodiment is shown, and other elements such as the first electrode 31, the second electrode 32 and the third electrode 33 in FIG. 4 may also be included in the embodiment although they are not shown in FIG. 6.

Embodiments of the present disclosure provide an array substrate. After forming the buffer layer 12 including the first via hole 121, the conductive structure 20 is formed in the first via hole 121. By configuring the conductive structure 20 such that the gate electrode 132 is electrically connected to the light shielding metal layer 11 by the conductive structure 20, the conductive structure 20 can be utilized to compensate for the portion of the light shielding metal layer 11 that is over etched away during formation of the first via hole 121, so that the gate electrode 132 and the light shielding metal layer 11 may be in better electrical connection.

Embodiments of the present disclosure provide a display panel including the array substrate according to any one of the preceding embodiments.

Herein, the display panel may be an LCD display panel or an OELD display panel.

In an embodiment, the display panel is an LCD display panel and a backlight source is provided to provide light to the display panel for display. The display panel includes an array substrate, an opposite substrate, and a liquid crystal layer disposed therebetween. The array substrate includes a thin film transistor, and the pixel electrode 18 electrically connected to the source electrode 133 of the thin film transistor. Further, the array substrate may further include a common electrode. The opposite substrate may include a black matrix and a color filter film 16. According to embodiments of the present disclosure, the color filter film 16 may be disposed on the opposite substrate or on the array substrate; the common electrode may be disposed on the array substrate or may be disposed on the opposite substrate.

When the display panel is an OLED display panel, since the OLED display panel is a self-luminous display panel, it can provide a light source to itself for display. The OLED display panel includes an array substrate and a package substrate, wherein the array substrate may include a thin film transistor, an anode electrically connected to the drain electrode 133 of the thin film transistor, a cathode, and an organic material functional layer between the anode and the cathode.

Embodiments of the present disclosure provides a display panel including the array substrate, in which the conductive structure 20 is provided in the first via hole 121. Compared with the related art, the conductive structure 20 may be formed after the buffer layer 12 including the first via hole 121 is formed and before the interlayer insulating layer 14 or the gate insulating layer 135 is formed. On the one hand, since the thickness of the buffer layer 12 (the thickness of the buffer layer is usually 4000 to 5000 Å) is less than the sum of the thicknesses of the buffer layer 12 and the interlayer insulating layer (the thickness of the interlayer insulating layer is usually 5000 to 6000 Å) 14 or the thickness of the buffer layer 12 is less than the sum of the thicknesses of the buffer layer 12 and the gate insulating layer 135, and it is only necessary to etch the buffer layer 12 to obtain the first via hole 121 before formation of the conductive structure 20, the etching amount of the light shielding metal layer 11 is less compared with the related art during etching the buffer layer 12, and thus the thickness of the portion of the metal light-shielding layer 11 whose orthographic projection on the substrate 10 overlaps the orthographic projection of the first via hole 121 on the substrate 10 is greater than that in related art; on the other hand, in the embodiment, the source electrode 133 is electrically connected to the conductive structure 20 through the second via hole 141 in the interlayer insulating layer 14 or the via hole in the gate insulating layer 135, and the conductive structure 20 can protect the light shielding metal layer 11 and prevent the light shielding metal layer 11 from being etched during formation of the interlayer insulating layer 14 or the gate insulating layer 135. Compared with the related art, the thickness of the portion of the metal light-shielding layer 11 whose orthographic projection on the substrate 10 overlaps the orthographic projection of the first via hole 121 on the substrate 10 is greater, and thus the problem of poor contact between the source electrode 133 and the light shielding metal layer 11 may be alleviated.

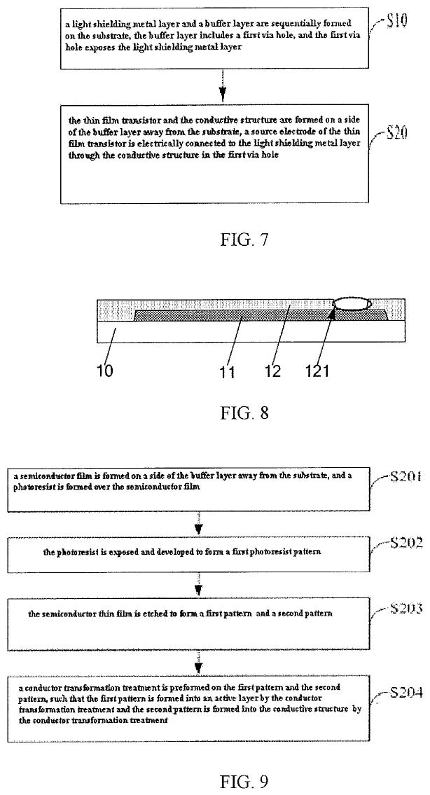

Embodiments of the present disclosure provide a method of manufacturing an array substrate, as shown in FIG. 7, which can be specifically implemented by the following steps:

In a step S10, as shown in FIG. 8, a light shielding metal layer 11 and a buffer layer 12 are sequentially formed on the substrate 10. The buffer layer 12 includes a first via hole 121, and the first via hole 121 exposes the light shielding metal layer 11.

Herein, the buffer layer 12 is made of an insulating material, for example, may be made of pure silicon oxide, and the first via hole 121 may be formed by dry etching.

According to embodiments of the present disclosure, the light shielding metal layer 11 may be made of a metal and have a function of conducting electricity and shielding light. According to the embodiments, a thickness of the light shielding metal layer 11 should be sufficient to block light.

In an embodiment, the light shielding metal layer 11 may be made of a high temperature and oxidation resistant metal material such as molybdenum, molybdenum-niobium alloy, or molybdenum-titanium alloy.

According to embodiments of the present disclosure, the array substrate is an array substrate for display, and the array substrate may be used for an OLED display panel, and may also be used for an LCD display panel.

When the array substrate is used for an OLED display panel, the OLED display panel further includes an OLED light emitting device. The OLED light emitting device includes an anode, an organic material functional layer and a cathode which are sequentially stacked; wherein the OLED light emitting device may be of a top emitting structure, or may also be of a bottom-emitting structure, or may be of a double-sided emitting structure in which both the anode and the cathode are transparent.

In an embodiment, the OLED light emitting device is of a bottom emitting structure, or a double-sided emitting structure in which both the anode and the cathode are transparent. In the embodiment, the light shielding metal layer 11 may be further used as a black matrix defining a sub-pixel region of the array substrate. On the basis of the above, since the light shielding metal layer 11 is electrically connected to the source electrode 133 of the thin film transistor through the conductive structure 20, the light shielding metal layer 11 is needed to be disposed just in the region where the orthographic projection of the thin film transistor on the substrate 10 is located. Those skilled in the art should know that the area where the thin film transistor is located cannot transmit light, and therefore, the light shielding metal layer 11 does not affect light transmission through the array substrate.

Of course, the light shielding metal layer 11 may also be disposed in other areas according to actual needs.

In a step S20, as shown in FIG. 2 and FIG. 3, the thin film transistor and the conductive structure 20 are formed on a side of the buffer layer 12 away from the substrate 10. A source electrode 133 of the thin film transistor is electrically connected to the light shielding metal layer 11 through the conductive structure 20 in the first via hole 121.

According to embodiments of the present disclosure, the conductive structure 20 may all be disposed in the first via hole 121; as shown in FIGS. 2 and 3, a portion of the conductive structure 20 is disposed in the first via hole 121 and another portion thereof is disposed on a surface of the buffer layer 12 away from the substrate 10. In the embodiment wherein the conductive structure 20 are all disposed in the first via hole 121, the conductive structure 20 may completely fill the first via hole 121 or partially fill the first via hole 121.

According to embodiments of the present disclosure, a size of the conductive structure 20 should at least satisfy that the source electrode 133 can be electrically connected to the light shielding metal layer 11 through the conductive structure 20, and the conductive structure 20 is not electrically connected to other structures of the thin film transistor (for example, the conductive structure is not electrically connected to the gate electrode).

According to embodiments of the present disclosure, the conductive structure 20 may be formed in various ways, for example, the conductive structure 20 may be separately formed from a single film; the conductive structure 20 may also be formed from the same film as other structures on the array substrate.

In an embodiment, the conductive structure 20 is formed by the same film as other structures on the array substrate. In this case, the conductive structure 20 may be obtained by the same manufacturing process as other structures on the array substrate, or may be obtained by a different manufacturing process from the other structures on the array substrate.

According to embodiments of the present disclosure, as shown in FIG. 2, the thin film transistor may be of a top gate type; as shown in FIG. 3, the thin film transistor may also be of a bottom gate type. Compared to a bottom-gate electrode thin film transistors, a top-gate type thin film transistors have a higher on-state current (Ion), a higher aperture ratio, and better stability.

In the embodiment shown in FIG. 2, the top gate type thin film transistor includes: an active layer 131, a gate insulating layer 135, a gate electrode 132, an interlayer insulating layer 14, and a source electrode 133 and a drain electrode 134 that are in contact with the active layer 131, which are formed on the substrate 10 in this order. In the embodiment shown in FIG. 3, the bottom gate type thin film transistor includes: a gate electrode 132, a gate insulating layer 135, an active layer 131, and a source electrode 133 and a drain electrode 134 in contact with the active layer 131, which are sequentially formed on the substrate 10.

As for the top gate type thin film transistor, the source electrode 133 is electrically connected to the conductive structure 20, located in the first via hole 121, through the second via hole 141 in the interlayer insulating layer 14.

As for the bottom gate type thin film transistor, the source electrode 133 is electrically connected to the conductive structure 20, located in the first via hole 121, through a via hole in the gate insulating layer 135.

The embodiments of the present disclosure provide a method for manufacturing an array substrate, which has the same technical effects as the foregoing array substrate, and details are not repeatedly described herein again.

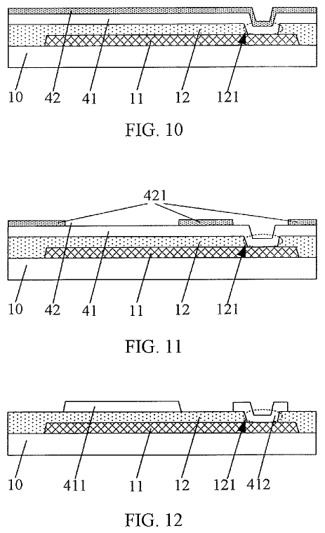

In an embodiment, the thin film transistor is a top gate type thin film transistor; the forming the thin film transistor and the conductive structure 20, as shown in FIG. 9, can be specifically realized by the following steps:

In a step S201, as shown in FIG. 10, a semiconductor film 41 is formed on a side of the buffer layer 12 away from the substrate 10, and a photoresist 42 is formed over the semiconductor film 41.

According to the embodiment of the present disclosure, the material of the semiconductor thin film 41 is selected such that after the semiconductor film 41 is subjected to the conductor transformation treatment, the source electrode region, the drain electrode region, and the conductive structure 20 having conductivity can be obtained.

In an embodiment, the material of the semiconductor thin film 41 may include a metal oxide such as at least one of IGZO and ITZO.

The material of the semiconductor film 41 may also include polysilicon.

In a step S202, as shown in FIG. 11, the photoresist 42 is exposed and developed to form a first photoresist pattern 421.

In a step S203, as shown in FIG. 12, the semiconductor thin film 41 is etched to form a first pattern 411 and a second pattern 412.

According to embodiments of the present disclosure, the semiconductor film 41 made of a different material is etched in a different manner. For example, when the material of the semiconductor film 41 includes a metal oxide, the first pattern 411 and the second pattern 412 may be formed by wet etching.

Based on this, the method further includes: after forming the first pattern 411 and the second pattern 412, peeling off the first photoresist pattern 421.

In a step S204, a conductor transformation treatment is preformed on the first pattern 411 and the second pattern 412, such that the first pattern 411 is formed into an active layer 131 by the conductor transformation treatment and the second pattern 412 is formed into the conductive structure 20 as shown in FIG. 2 by the conductor transformation treatment.

It should be noted that the process of the conductor transformation treatment varies depending on the material of the semiconductor thin film 41.

In an embodiment, the material of the semiconductor film 41 is a metal oxide, and the semiconductor film may be subjected to a conductor transformation treatment by a chemical vapor deposition method, in which a gas containing the hydrogen atom may be used. The gas containing the hydrogen atom may be hydrogen gas (H₂) or ammonia (NH₃). The hydrogen atoms (or ions) may be used to perform an ionic bombardment on the metal oxide to remove oxygen ions in the metal oxide. In another embodiment, the semiconductor film 41 can be subjected to a conductor transformation treatment by dry etching.

Since the dry etching has no etching effect on the metal oxide 41, the atom contained in the gas used during the dry etching may be utilized to perform a bombardment on the metal oxide to break chemical bond between oxygen and metal of the metal oxide so as to remove the oxygen from the metal oxide. The gas used for the dry etching may be helium gas, and the atoms for performing a bombardment on the metal oxide are helium atoms.

Herein, the semiconductor thin film 41 is subjected to a conductor transformation treatment, and in practice, the patterns of the active layer 131 and the conductive structure 20 may be formed by the semiconductor thin film 41. In an embodiment, the active layer 131 corresponds to the first pattern 411, the conductive structure 20 corresponds to the second pattern 412, and after the first pattern 411 and the second pattern 412 are formed, the first pattern 411 and the second pattern 412 are subjected to a conductor transformation treatment to obtain a source electrode region, a drain electrode region, and the conductive structure 20 that have conductivity, respectively.

The first pattern 411 and the second pattern 412 may be simultaneously subjected to a conductor transformation treatment, or the first pattern 411 and the second pattern 412 may be separately subjected to a conductor transformation treatment. In an embodiment, the first pattern 411 and the second pattern 412 are simultaneously subjected to a conductor transformation treatment to simplify the fabrication process of the array substrate and reduce the number of masks.

In the embodiment, the active layer 131 includes a channel region, a source electrode region and a drain electrode region respectively on either side of the channel region, an orthographic projection of the channel region on the substrate 10 overlaps an orthographic projection of the gate electrode 132 on the substrate 10. The source electrode 133 is electrically connected to the conductive structure 20 through the second via hole 141 in the interlayer insulating layer 14. The source electrode 133 is also electrically connected to the source electrode region through the third via hole 142 in the interlayer insulating layer 14. The drain electrode 134 is electrically connected to the drain electrode region through the fourth via hole 143 in the interlayer insulating layer 14.

Herein, in order to improve an ohmic contact between the source electrode 133 and the drain electrode 134 and the active layer 131, such that the top gate type thin film transistor has better switching characteristics, the source electrode region and the drain electrode region in the active layer 131 are both obtained by a conductor transformation treatment.

According to embodiments of the present disclosure, the orthographic projection of the channel region on the substrate 10 may exactly completely overlap the orthographic projection of the gate electrode 132 on the substrate 10. According to embodiments of the present disclosure, the orthographic projection of the channel region on the substrate 10 may also extend beyond the area where the orthographic projection of the gate electrode 132 on the substrate 10 is located. In other words, the orthographic projection of the channel region on the substrate 10 does not exactly completely coincide with the orthographic projections of the source electrode 133 and the drain electrode 134 on substrate 10.

In the embodiment of the present disclosure, since the patterns of the active layer 131 and the conductive structure 20 are formed by the same semiconductor film 41, the fabrication processes can be simplified and the number of masks can be reduced.

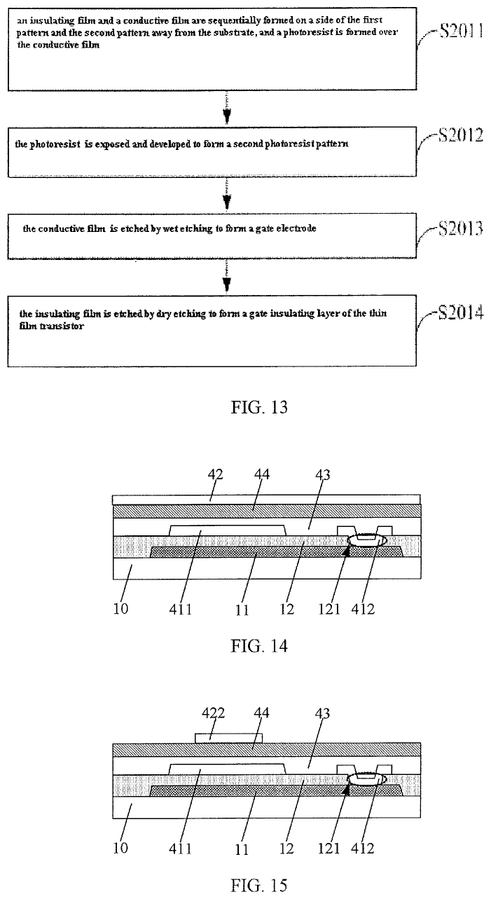

Further, in an embodiment, after the first pattern 411 and the second pattern 412 are formed, and before the first pattern 411 and the second pattern 412 are subjected to the conductor transformation treatment, as shown in FIG. 13, the method of forming the thin film transistor further includes the following steps.

In a step S2011, as shown in FIG. 14, an insulating film 43 and a conductive film 44 are sequentially formed on a side of the first pattern 411 and the second pattern 412 away from the substrate 10, and a photoresist 42 is formed over the conductive film 44.

Here, the insulating film 43 is used to form the gate insulating layer 135. Therefore, the material of the insulating film 43 should at least satisfy the conditions of using as the gate insulating layer 135. The conductive film 44 is used to form the gate electrode 132, and therefore, the material of the conductive film 44 at least satisfies the conditions of using as the gate electrode 132.

In a step S2012, as shown in FIG. 15, the photoresist 42 is exposed and developed to form a second photoresist pattern 422.

In a step S2013, as shown in FIG. 16, the conductive film 44 is etched by wet etching to form a gate electrode 132.

According to embodiments of the present disclosure, during wet-etching the conductive film 44, there is less or no influence on the insulating film 43.

According to embodiments of the present disclosure, since etching liquid may etch the conductive film 44 from side thereof during wet-etching the conductive film 44 to form the gate electrode 132, the size of the gate electrode 132 is less than or equal to the size of the second photoresist pattern 422 and an orthographic projection of the second photoresist pattern 422 on the substrate 10 completely covers the orthographic projection of the gate electrode 132 on the substrate 10.

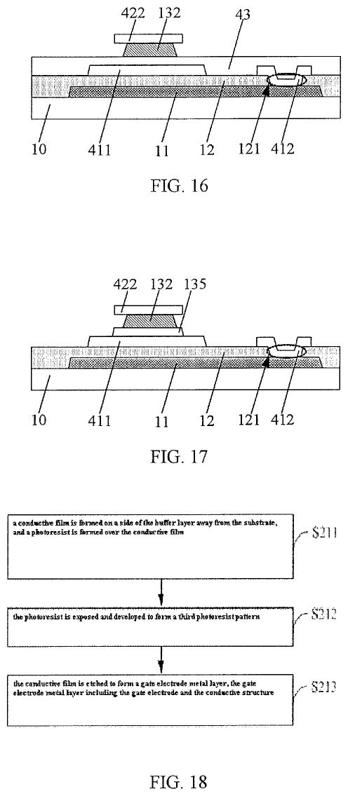

In a step S2014, as shown in FIG. 17, the insulating film 43 is etched by dry etching to form a gate insulating layer 135 of the thin film transistor.

According to embodiments of the present disclosure, in the process of dry-etching the insulating film 43, there is less or no influence on the gate electrode 132.

According to the embodiment of the present disclosure, since the etching gas etches the insulating film 43 in the direction from the conductive film 44 toward the insulating film 43 during dry-etching the insulating film 43 to form the gate insulating layer 135, the size of the gate insulating layer 135 is substantially equal to the size of the second photoresist pattern 422, and the orthographic projection of the second photoresist pattern 422 on the substrate 10 completely covers the orthographic projection of the gate electrode 132 on the substrate 10.

The conducting a conductor transformation treatment on the first pattern 411 and the second pattern 412 includes: covering the first pattern 411 with the second photoresist pattern 422, and performing a conductor transformation treatment on the first pattern 411 to obtain a source electrode region and a drain electrode region including conductor; conducting a conductor transformation treatment on the second pattern 412 to obtain the conductive structure 20.

That is, the second photoresist pattern 422 covers a portion of the first pattern 411 (the channel region of the active layer), and the portion of the first pattern 411 that is not covered by the second photoresist pattern 422 and the second pattern 412 are subjected to the conductor transformation treatment.

On this basis, after the first pattern 411 and the second pattern 412 are subjected to the conductor transformation treatment, the second photoresist pattern 422 is peeled off.

In the embodiment of the present disclosure, the orthographic projection of the gate insulating layer 135 on the substrate 10 completely overlaps the orthographic projection of the channel region on the substrate 10, that is, the second photoresist pattern 422 used to form the gate insulating layer 135 and the photoresist pattern used for conducting the conductor transformation treatment on the first pattern 411 and the second pattern 422 may be the same photoresist pattern, which simplifies the manufacturing process of the array substrate and reduces the number of masks.

In an embodiment, the thin film transistor is a bottom gate type thin film transistor; the forming the thin film transistor and the conductive structure 20, as shown in FIG. 18, can be specifically realized by the following steps.

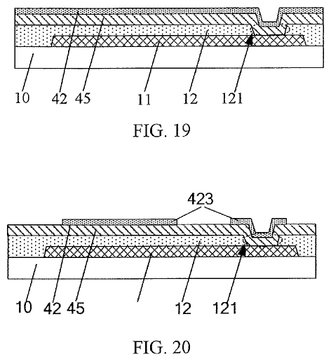

In a step S211, as shown in FIG. 19, a conductive film 45 is formed on a side of the buffer layer 12 away from the substrate 10, and a photoresist 42 is formed over the conductive film 45.

Here, the conductive film 45 is used to form the gate electrode 132 and the conductive structure 20, and therefore, the material of the conductive film 45 should satisfy at least conditions of using as the gate electrode 132 and the conductive structure 20.

In a step S212, as shown in FIG. 20, the photoresist 42 is exposed and developed to form a third photoresist pattern 423.

In a step S213, as shown in FIG. 3, the conductive film 45 is etched to form a gate electrode metal layer, the gate electrode metal layer including the gate electrode 132 and the conductive structure 20.

In the embodiment of the present disclosure, since the gate electrode 132 and the conductive structure 20 are formed by a single patterning process, the fabrication processes may be simplified and the number of masks may be reduced, compared with the scheme in which the conductive structure 20 and the active layer 131 are formed by a single patterning process, the embodiment of the present disclosure may also omit the step of conducting the conductor transformation treatment to obtain the conductive structure 20.

In an embodiment, as shown in FIG. 4, the method further includes: forming a first electrode 31, a second electrode 32, and a third electrode 33 sequentially on the substrate 10, the first electrode 31, the second electrode 32, and the third electrodes 33 being insulated from one another and constitute storage capacitors. FIG. 4 just shows a storage capacitor of the embodiment in which the top gate type thin film transistor is provided. As for the bottom gate type thin film transistor, the storage capacitor may also be included.

It should be noted that the first electrode 31, the second electrode 32 and the third electrode 33 being insulated from one another means that every two of the first electrode 31, the second electrode 32 and the third electrode 33 are insulated from each other. That is, the first electrode 31 and the second electrode 32 are insulated from each other, the first electrode 31 and the third electrode 33 are insulated from each other, and the second electrode 32 and the third electrode 33 are insulated from each other.

The first electrode 31, the second electrode 32, and the third electrode 33 constitute a capacitor in a sandwich structure.

In the embodiment of the present disclosure, the storage capacitor of the sandwich structure may reduce an area of the orthographic projection of the storage capacitor on the substrate 10 and in turn increase aperture ratio of the array substrate while obtaining the same capacitance value of the storage capacitor as the storage capacitor having two electrodes.

In an embodiment, as shown in FIG. 4, the array substrate further includes a pixel electrode 18; the first electrode 31 and the pixel electrode 18 are obtained by a single patterning process, and the second electrode 32 and the source electrode 133 and the drain electrode 134 is obtained by a single patterning process, and the third electrode 33 and the conductive structure 20 are obtained by a single patterning process.

In the embodiment of the present disclosure, since the first electrode 31 and the pixel electrode 18 are subjected to the same patterning process, the second electrode 32 and the source electrode 133 and the drain electrode 134 are subjected to the same patterning process, and the third electrode 33 and the conductive structure are subjected to the same patterning process, the manufacturing process of the array substrate may be simplified and the number of masks may be reduced.

The above is only the specific embodiments of the present disclosure, but the scope of the present disclosure is not limited thereto, and any person skilled in the art can easily think of changes or substitutions within the technical scope of the disclosure. They should be covered within the scope of protection of the present disclosure. Therefore, the scope of protection of the present disclosure should be defined by the scope of protection of the claims.

1. An array substrate comprising:
a substrate;
a light shielding metal layer on the substrate;
a buffer layer on a side, on which the light shielding metal layer is, of the substrate including the light shielding metal layer; and
a thin film transistor on a side of the buffer layer away from the substrate, the thin film transistor including a gate electrode, an active layer, and a source electrode and a drain electrode;
the array substrate further comprises:
a first via hole in the buffer layer, the first via hole exposing the light shielding metal layer; and
a conductive structure in the first via hole, the source electrode being electrically connected to the light shielding metal layer through the conductive structure.

2. The array substrate as claimed in claim 1, wherein the thin film transistor is a top gate type thin film transistor;
the active layer includes a channel region, and a source electrode region and a drain electrode region on either side of the channel region, an orthographic projection of the channel region on the substrate overlapping an orthographic projection of the gate electrode on the substrate; the source electrode is electrically connected to the conductive structure through a second via hole in an interlayer insulating layer and is further electrically connected to the source electrode region through a third via hole in the interlayer insulating layer, and the drain electrode is electrically connected to the drain electrode region through a fourth via hole in the interlayer insulating layer;
the source electrode region, the drain electrode region, and the conductive structure are obtained by converting corresponding portions of a same semiconductor film into a conductor, and a first pattern of the conductor converted from the semiconductor film includes the source electrode region and the drain electrode region, and a second pattern of the conductor converted from the semiconductor film includes the conductive structure.

3. The array substrate as claimed in claim 1, wherein the thin film transistor is a top gate type thin film transistor; the active layer includes a channel region, and a source electrode region and a drain electrode region on either side of the channel region, an orthographic projection of the channel region on the substrate overlapping an orthographic projection of the gate electrode on the substrate; the source electrode is electrically connected to the conductive structure through a second via hole in an interlayer insulating layer and is further electrically connected to the source electrode region through a third via hole in the interlayer insulating layer; and the drain electrode is electrically connected to the drain electrode region through a fourth via hole in the interlayer insulating layer;
the gate electrode and the conductive structure are formed by a same conductive film, a first pattern of the conductive film includes the gate electrode, and a second pattern of the conductive film includes the conductive structure.

4. The array substrate as claimed in claim 2, wherein the thin film transistor further comprises a gate insulating layer disposed between the active layer and the gate electrode; and
an orthographic projection of the gate insulating layer on the substrate completely overlaps an orthographic projection of the channel region on the substrate.

5. The array substrate as claimed in claim 3, wherein the thin film transistor further comprises a gate insulating layer disposed between the active layer and the gate electrode; and
an orthographic projection of the gate insulating layer on the substrate completely overlaps an orthographic projection of the channel region on the substrate.

6. The array substrate as claimed in claim 1, wherein the thin film transistor is a bottom gate type thin film transistor; and
the conductive structure and the gate electrode are obtained from a same conductive film, wherein a first pattern of the conductive film comprises the gate electrode, and a second pattern of the conductive film comprises the conductive structure, the bottom gate type thin film transistor comprises a gate insulating layer and the source electrode is electrically connected to the conductive structure through a fifth via hole in the gate insulating layer.

7. The array substrate of claim 1, wherein the array substrate further comprises a storage capacitor;
the storage capacitor includes a first electrode, a second electrode, and a third electrode that are stacked, and the first electrode, the second electrode, and the third electrode are insulated from one another.

8. The array substrate as claimed in claim 7, wherein the array substrate further comprises a pixel electrode, the pixel electrode being electrically connected to the source electrode of the thin film transistor; and
the first electrode is disposed in a same layer as the pixel electrode, the second electrode is disposed in a same layer as the source electrode and the drain electrode, and the third electrode is disposed in a same layer as the conductive structure.

9. The array substrate of claim 1, wherein the array substrate is an organic light-emitting diode array substrate, the organic light-emitting diode array substrate further comprises an organic light-emitting diode type light-emitting device, and the organic light-emitting diode type light-emitting device includes an anode, a functional layer of an organic material, and a cathode, which are sequentially stacked; and
the array substrate includes a pixel electrode, the pixel electrode functions as the anode.

10. The array substrate as claimed in claim 1, wherein the thin film transistor is a double-gate type thin film transistor, and the gate electrode is electrically connected to the light shielding metal layer via a conductive block and the conductive structure.

11. A display panel comprising the array substrate as claimed in claim 1.

12. A method of manufacturing an array substrate, wherein the method comprises:
forming a light shielding metal layer and a buffer layer on a substrate in order, wherein the buffer layer includes a first via hole, the first via hole exposing the light shielding metal layer; and
forming a thin film transistor and a conductive structure on a side of the buffer layer away from the substrate, wherein a source electrode of the thin film transistor is electrically connected to the light shielding metal layer through the conductive structure located in the first via hole.

13. The method of manufacturing an array substrate as claimed in claim 12, wherein the thin film transistor is a top gate type thin film transistor;
the forming the thin film transistor and the conductive structure comprises:
forming a semiconductor film on the side of the buffer layer away from the substrate, and forming photoresist over the semiconductor film;
exposing and developing the photoresist to form a first photoresist pattern;
etching the semiconductor film to form a first pattern of the semiconductor film and a second pattern of the semiconductor film; and
conducting a conductor transformation treatment on the first pattern of the semiconductor film and the second pattern of the semiconductor film, the first pattern of the semiconductor film being subjected to the conductor transformation treatment to form an active layer of the thin film transistor, the second pattern of the semiconductor film being subjected to the conductor transformation treatment to form the conductive structure;
wherein the active layer includes a channel region, and a source electrode region and a drain electrode region on either side of the channel region, an orthographic projection of the channel region on the substrate overlapping an orthographic projection of a gate electrode of the thin film transistor on the substrate; the source electrode being electrically connected to the conductive structure through a second via hole in an interlayer insulating layer and being further electrically connected to the source electrode region through a third via hole in the interlayer insulating layer; and the drain electrode is electrically connected to the drain electrode region through a fourth via hole in the interlayer insulating layer.

14. The method of manufacturing an array substrate as claimed in claim 13, wherein a material of the semiconductor film is a metal oxide;
the conducting a conductor transformation treatment on the first pattern of the semiconductor film and the second pattern of the semiconductor film comprises:
conducting a conductor transformation treatment on the first pattern of the semiconductor film and the second pattern of the semiconductor film by a chemical vapor deposition method using a gas containing hydrogen atoms; or
conducting a conductor transformation treatment on the first pattern and the second pattern by dry etching.

15. The method of manufacturing an array substrate as claimed in claim 13, wherein after forming the first pattern of the semiconductor film and the second pattern of the semiconductor film, and before conducting the conductor transformation treatment on the first pattern of the semiconductor film and the second pattern of the semiconductor film, the forming the thin film transistor further comprises:
forming an insulating film and a conductive film sequentially on a side of the first pattern of the semiconductor film and the second pattern of the semiconductor film away from the substrate, and forming photoresist over the conductive film;
exposing and developing the photoresist to form a second photoresist pattern;
wet-etching the conductive film to form the gate electrode;
dry-etching the insulating film to form a gate insulating layer of the thin film transistor; and
wherein the conducting a conductor transformation treatment on the first pattern of the semiconductor film and the second pattern of the semiconductor film comprises:
covering the first pattern of the semiconductor film with the second photoresist pattern, and conducting a conductor transformation treatment on the first pattern of the semiconductor film to obtain the source electrode region and the drain electrode region including a conductor converted; and
conducting a conductor transformation treatment on the second pattern of the semiconductor film to obtain the conductive structure.

16. The method of manufacturing an array substrate as claimed in claim 12, wherein the thin film transistor is a bottom gate type thin film transistor;
the forming the thin film transistor and the conductive structure comprises:
forming a conductive film on the side of the buffer layer away from the substrate, and forming photoresist over the conductive film;
exposing and developing the photoresist to form a third photoresist pattern; and
etching the conductive film to form a gate electrode metal layer, the gate electrode metal layer including the gate electrode and the conductive structure.

17. The method of manufacturing an array substrate as claimed in claim 12, wherein the method further comprises:
forming a first electrode, a second electrode, and a third electrode sequentially on the substrate, the first electrode, the second electrode, and the third electrode being insulated from one another and constituting a storage capacitor.

18. The method of manufacturing an array substrate as claimed in claim 17, wherein the array substrate further comprises a pixel electrode;
the first electrode and the pixel electrode are obtained by a single patterning process, the second electrode and the source electrode and the drain electrode are obtained by a single patterning process, and the third electrode and the conductive structure are obtained by a single patterning process.
